(19) United States
(12) Patent Application Publication
(10) Pub. No.: US 2009/0256984 A1
(43) Pub. Date: Oct. 15, 2009

(54) DISPLAY SUBSTRATE, METHOD FOR MANUFACTURING THE SAME AND DISPLAY APPARATUS HAVING THE SAME

(75) Inventors: Sang-Hun LEE, Suwon-si (KR); Byoung-Joo KIM, Anyang-si (KR); Gwan-Soo KIM, Seoul (KR); Sun-Young CHANG, Bucheon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/369,168

(22) Filed: Feb. 11, 2009

(30) Foreign Application Priority Data
Apr. 15, 2008 (KR) 2008-34697

(51) Int. Cl. G02F 1/1333; H01L 27/088; H01L 21/00

(52) U.S. Cl. 349/43; 257/59; 438/29; 257/E21.535; 257/E27.06

(57) ABSTRACT

A display substrate includes a base substrate, a signal line, a thin-film transistor (“TFT”), a pixel electrode, a color filter and a light-blocking part. The signal line and the TFT are formed on the base substrate. The TFT is electrically connected to the signal line. The pixel electrode is formed in a unit pixel area of the base substrate and is electrically connected to the TFT. The color filter is formed in the unit pixel area. The light-blocking part includes an organic pattern formed on the base substrate and a light-blocking pattern formed on the organic pattern. The organic pattern covers the TFT and is formed along a longitudinal axis of the signal line to define at least a portion of a periphery of the color filter. A size and a shape of the light-blocking pattern are substantially the same as a size and a shape of the organic pattern.

This application claims priority to Korean Patent Application No. 2008-34697, filed on Apr. 15, 2008, and all the benefits accruing therefrom under 35 U.S.C. § 119, the contents of which in its entirety are herein incorporated by reference.

### BACKGROUND OF THE INVENTION

1. Field of the Invention

The present invention relates to a display substrate, a method for manufacturing the display substrate and a display apparatus having the display substrate. More particularly, the present invention relates to a display substrate having an improved display quality, a method for manufacturing the display substrate and a liquid crystal display apparatus having the display substrate.

2. Description of the Related Art

In general, a liquid crystal display (“LCD”) apparatus includes a first substrate having a thin-film transistor (“TFT”) and a pixel electrode, a second substrate facing the first substrate, and a liquid crystal layer disposed between the first substrate and the second substrate. In addition, the second substrate typically includes a color filter, located in an area corresponding to the pixel electrode, and a light-blocking pattern formed along a peripheral outline of the color filter. Recently, however, a color filter on array (“COA”) LCD apparatus has been developed. In the COA LCD apparatus, the first substrate includes the color filter and the light-blocking pattern.

In forming the first substrate of the COA type LCD apparatus, a signal line and a TFT are formed on a base substrate, and a passivation layer including silicon nitride (“SiNx”), for example, is then formed on the base substrate to cover the signal line and the TFT. Then, a light-blocking photosensitive film is formed on the passivation layer, and the light-blocking photosensitive film is patterned to form a light-blocking pattern on a portion of the passivation layer. A color filter ink is then jetted onto another portion of the passivation layer (on which the light-blocking pattern is not formed) and the color filter ink is dried to form a color filter on the passivation layer. A pixel electrode is then formed on the color filter.

In forming the first substrate of the COA type LCD apparatus, however, the light-blocking photosensitive film makes direct contact with the passivation layer. As a result, a remaining portion of the light-blocking photosensitive film remains on the passivation layer, and is therefore on the passivation layer when the light-blocking photosensitive film is patterned thereon. Therefore, when the remaining portion of the light-blocking photosensitive film is located at a portion of the passivation where the color filter is subsequently formed, defects are formed therein. As a result, an image displayed on the COA type LCD apparatus includes spots, and a display quality of the image is thereby reduced, e.g., is thereby degraded.

In addition, to planarize the entire surface of the first substrate, a thickness of the light-blocking pattern is required to be substantially the same as a thickness of the color filter. However, the thickness of the color filter is generally approximately 3 μm, and the thickness of the light-blocking pattern is therefore required to be approximately 3 μm as well. As a result, it is difficult to precisely form the light-blocking pattern to have a predetermined shape disposed at an accurate position on the first substrate when patterning the light-blocking photosensitive film.

### BRIEF SUMMARY OF THE INVENTION

Exemplary embodiments of the present invention provide a display substrate having an improved display quality, a method for manufacturing the above-mentioned display having an increased efficiency, and a display apparatus having the display substrate.

According to an exemplary embodiment of the present invention, a display substrate includes a base substrate, a signal line, a thin-film transistor (“TFT”), a pixel electrode, a color filter and a light-blocking part.

The signal line is formed on the base substrate. The TFT is formed on the base substrate and is electrically connected to the signal line. The pixel electrode is electrically connected to the TFT, and is formed in a unit pixel area of the base substrate. The color filter is formed in the unit pixel of the base substrate. The light-blocking part includes an organic pattern formed on the base substrate and a light-blocking pattern formed on the organic pattern. The organic pattern is formed along a longitudinal axis of the signal line to define at least a portion of a periphery of the color filter and covers the TFT. A size and a shape of the light-blocking pattern are substantially the same as a size and a shape of the organic pattern.

The organic pattern may have a hydrophilic property, and the light-blocking pattern may have a hydrophobic property. A thickness of the light-blocking part may be approximately the same as a corresponding thickness of the color filter. A thickness of the organic pattern may be approximately equal to or greater than a corresponding thickness of the light-blocking pattern.

The display substrate may further include an organic protective layer formed between the pixel electrode and the color filter to cover the color filter and the light-blocking part.

The pixel electrode may be formed on the color filter, and may make electric contact with a drain electrode of the TFT through a contact hole is formed through the light-blocking part.

The display substrate may further include a plurality of the signal lines, and the plurality of signal lines may include a gate line and a data line. The gate line may be formed along a first direction and be electrically connected to a gate electrode of the TFT. The data line may be formed along a second direction, substantially perpendicular to the first direction, and may be electrically connected to a source electrode of the TFT.

The data line may include a first data line and a second data line. The first data line may provide a first data voltage having a first level to the pixel electrode. The second data line may be disposed adjacent to the first data line, and may provide a second data voltage, having a second level lower than the first level, to the pixel electrode. The light-blocking part may be disposed between the first data line and the second data line, and may at least partially overlap the first data line and the second data line.

According to an alternative exemplary embodiment of the present invention, a method for manufacturing a display substrate includes forming a signal line and a TFT electrically connected to the signal line on a base substrate, forming a light-blocking part including an organic pattern on the base substrate and a light-blocking pattern on the organic pattern, forming a color filter and forming a pixel electrode, electrically connected to the thin-film transistor, on the color filter in a unit pixel area of the base substrate in which the light-blocking part is not formed. The organic pattern is formed along a longitudinal axis of the signal line to define at least a portion of a periphery of the color filter and cover the TFT. A size and a shape of the light-blocking pattern are substantially the same as a size and a shape of the organic pattern. The color filter is formed in the unit pixel area of the base substrate in which the light-blocking part is not formed.

The light-blocking part may be formed by sequentially forming an organic photosensitive film and a light-blocking photosensitive film on the base substrate to cover the signal line and the TFT. Then, the organic pattern and the light-blocking pattern may be formed by patterning the organic photosensitive film and the light-blocking photosensitive film through a photolithography process.

The organic photosensitive film and the light-blocking photosensitive film may be formed by attaching a dry film to the base substrate. The dry film includes the light-blocking photosensitive film and the organic photosensitive film sequentially formed on a base film. Then, the base film is removed from the light-blocking photosensitive film and the organic photosensitive film.

The dry film may be attached to the base substrate by aligning the dry film on the base substrate and then attaching the organic photosensitive film and the light-blocking photosensitive film to the base substrate by pressing and/or heating the dry film.

The organic photosensitive film and the light-blocking photosensitive film may have substantially a same type of photo resist, e.g., a same photoresistance. More specifically, in an exemplary embodiment of the present invention, for example, the organic photosensitive film and the light-blocking photosensitive film may be negative type photo resists.

The color filter may be formed by jetting a color filter ink onto the unit pixel area of the base substrate on which the light-blocking part is not formed. Then, the color filter ink may be dried to form the color filter.

The organic pattern may have a hydrophilic property to have high affinity for the color filter ink (relative to the light-blocking pattern), and the light-blocking pattern may have a hydrophobic property to have low affinity for the color filter ink (relative to the organic pattern). A thickness of the color filter formed by drying the color filter ink may be substantially the same as a corresponding thickness of the light-blocking part.

According to another alternative exemplary embodiment of the present invention, a display apparatus includes a first substrate, a second substrate facing the first substrate, and a liquid crystal layer disposed between the first substrate and the second substrate.

The first substrate includes a base substrate, a signal line, a TFT, a pixel electrode, a color filter and a light-blocking part. The signal line is formed on the base substrate. The TFT is formed on the base substrate and is electrically connected to the signal line. The pixel electrode is formed in a unit pixel area of the base substrate and is electrically connected to the TFT. The color filter is formed in the unit pixel area of the base substrate. The light-blocking part includes an organic pattern formed on the base substrate and a light-blocking pattern formed on the organic pattern. The organic pattern is formed along a longitudinal axis of the signal line to define at least a portion of a periphery of the color filter and covers the TFT. A size and a shape of the light-blocking pattern are substantially the same as a size and a shape of the organic pattern.

The second substrate may include a counter substrate and a common electrode. The counter substrate may face the first substrate. The common electrode may be formed on a surface of the counter substrate facing the first substrate.

According to exemplary embodiments of the present invention, an organic pattern is formed beneath a light-blocking pattern and the light-blocking pattern is thereby prevented from making direct contact with a passivation layer thereunder. Thus, a remaining portion of the light-blocking photosensitive film is effectively prevented from remaining on the passivation layer when the light-blocking photosensitive film is patterned, and a display quality of an image is substantially enhanced.

In addition, the organic photosensitive film is formed beneath the light-blocking photosensitive film, so that a thickness of the light-blocking photosensitive film is substantially decreased. Thus, the light-blocking pattern may be precisely formed at an accurate position and with a predetermined shape when patterning the light-blocking photosensitive film.

### BRIEF DESCRIPTION OF THE DRAWINGS

The above and other aspects, features and advantages of the present invention will a become more readily apparent by describing in further detail exemplary embodiments thereof with reference to the accompanying drawings, in which:

FIG. 1 is a plan view of a display substrate according to an exemplary embodiment of the present invention;

FIG. 2 is a partial cross-sectional view taken along line II-II′ of FIG. 1;

FIG. 3 is a partial cross-sectional view taken along line III-III′ of FIG. 1;

FIG. 4 is a partial cross-sectional view which illustrates a process for forming a thin-film transistor (“TFT”) and a data line on a base substrate in a method for manufacturing a display substrate according to an exemplary embodiment of the present invention;

FIG. 5 is a partial cross-sectional view which illustrates a process for aligning a dry film in the base substrate in the method for manufacturing the display substrate according to the exemplary embodiment of the present invention shown in FIG. 4;

FIG. 6 is a partial cross-sectional view which illustrates a process for attaching the dry film to the base substrate in the method for manufacturing the display substrate according to the exemplary embodiment of the present invention shown in FIG. 5;

FIG. 7 is a partial cross-sectional view which illustrates a process for exposing an organic photosensitive film and a light-blocking photosensitive film attached to the base substrate in the method for manufacturing the display substrate according to the exemplary embodiment of the present invention shown in FIG. 6;

FIG. 8 is a partial cross-sectional view which illustrates a process for patterning an exposed organic photosensitive film and an exposed light-blocking photosensitive film in the method for manufacturing the display substrate according to the exemplary embodiment of the present invention shown in FIG. 7;

FIG. 9 is a partial cross-sectional view which illustrates a process for jetting a color filter ink onto a unit pixel of the base substrate in the method for manufacturing the display substrate according to the exemplary embodiment of the present invention shown in FIG. 8;

FIG. 10 is a partial cross-sectional view which illustrates a process for drying the color filter ink jetted on the base substrate in the method for manufacturing the display substrate according to the exemplary embodiment of the present invention shown in FIG. 9;

FIG. 11 is a partial cross-sectional view which illustrates a process for forming a pixel electrode on a color filter in the method for manufacturing the display substrate according to the exemplary embodiment of the present invention shown in FIG. 10;

FIG. 12 is a partial cross-sectional view of a display apparatus having the display substrate according to the exemplary embodiment of the present invention shown in FIG. 1;

FIG. 13 is a partial cross-sectional view of a display substrate according to an alternative exemplary embodiment of the present invention; and

FIG. 14 is a partial cross-sectional view of a display substrate according to yet another alternative exemplary embodiment of the present invention.

### DETAILED DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

Hereinafter, the exemplary embodiments present invention will be described in further detail with reference to the accompanying drawings.

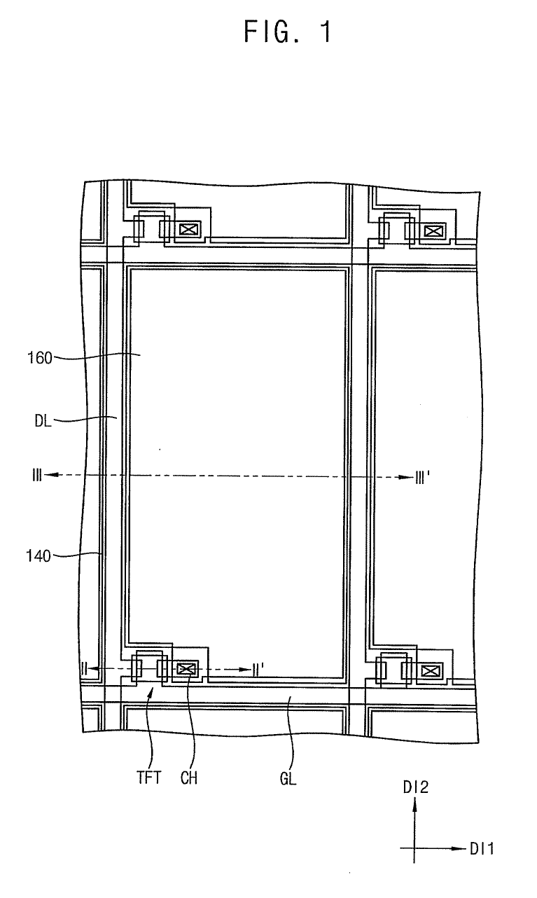

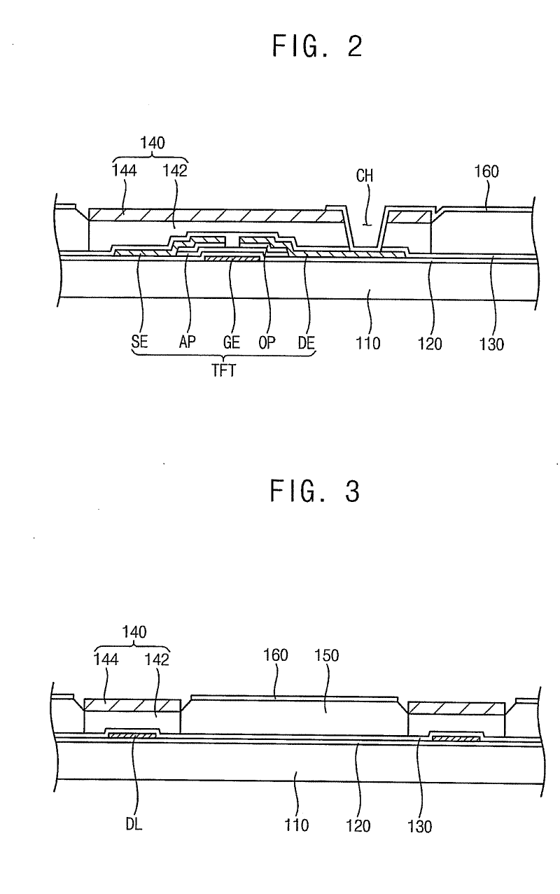

FIG. 1 is a plan view of a display substrate according to an exemplary embodiment of the present invention. FIG. 2 is a partial cross-sectional view taken along line II-II′ of FIG. 1. FIG. 3 is a partial cross-sectional view taken along line III-III′ of FIG. 1.

Referring to FIGS. 1, 2 and 3, the display apparatus according to an exemplary embodiment includes a base substrate 110, a plurality of gate lines GL, a gate insulating layer 120, a plurality of data lines DL, a plurality of thin-film transistors (“TFT”), a passivation layer 130, a light-blocking part 140, a plurality of color filters 150 and a plurality of pixel electrodes 160.

The base substrate 110 according to an exemplary embodiment may have a plate shape, e.g., a substantially cubic rectangular shape, and may include a transparent material such as glass, quartz and/or synthetic resin, for example, but alternative exemplary embodiments are not limited to the shape or materials listed above.

Gate lines GL of the plurality of gate lines GL extend along a first direction DI1 on the base substrate 110. The gate lines GL are disposed substantially in parallel to each other and substantially perpendicular to a second direction DI2 crossing the first direction DI1, as shown in FIG. 1.

The gate insulating layer 120 is formed on the base substrate 110 to substantially cover the gate lines GL. In an exemplary embodiment of the present invention, the gate insulating layer 120 is an inorganic insulating layer including silicon oxide (“SiOx”) or silicon nitride (“SiNx”), for example, but alternative exemplary embodiments are not limited thereto.

Data lines DL of the plurality of data lines DL extend along the second direction DI2 on the gate insulating layer 120. The data lines DL are disposed in parallel to each other, as shown in FIG. 1. In an exemplary embodiment of the present invention, the data lines DL and the gate lines GL are signal lines.

Each TFT of the plurality of the TFTs includes a gate electrode GE, an active pattern AP, an ohmic contact pattern OP, a source electrode SE and a drain electrode DE (best shown in FIG. 2).

The gate electrode GE is divided from the gate line GL along the second direction DI2, e.g., branches from the gate line GL in the second direction DI2, and is covered by the gate insulating layer 120. Put another way, the gate electrode GE according to an exemplary embodiment may be a portion of the gate line GL.

The active pattern AP is formed on the gate insulating layer 120 to overlap the gate electrode GE. The ohmic contact pattern OP is formed on the active pattern AP, and is divided into two parts. Specifically, the active pattern AP according to an exemplary embodiment may include, for example, amorphous silicon (“a-Si”), and the ohmic contact pattern OP may include amorphous silicon doped with n-type dopants (“n+a-Si”) having a high concentration, but alternative exemplary embodiments of the present invention are not limited thereto.

The source electrode SE branches from the data line DL along the first direction DI1, and a portion of the source electrode SE is formed on a first portion of the ohmic contact pattern OP. The drain electrode DE is spaced apart from the source electrode SE and is formed on the gate insulating layer 120. A portion of the drain electrode DE is formed on a second portion of the ohmic contact pattern OP separate from the first portion thereof, as shown in FIG. 2.

The passivation layer 130 is formed on the gate insulating layer 120 to cover the data lines DL and the TFTs. In an exemplary embodiment, the passivation layer 130 includes an inorganic insulating layer, such as silicon oxide (“SiOx”), for example, or, alternatively, silicon nitride (“SiNx”). In an alternative exemplary embodiment of the present invention, the passivation layer 130 may be omitted.

Still referring to FIGS. 1, 2 and 3, the light-blocking part 140 is formed on the passivation layer 130. Specifically, the light-blocking part 140 is formed on the passivation layer 130 to block light from reaching the TFT from outside the display apparatus according to an exemplary embodiment. The light-blocking part 140 includes an organic pattern 142 and a light-blocking pattern 144 formed on the organic pattern 142, as shown in FIGS. 2 and 3.

In an exemplary embodiment, the organic pattern 142 is formed on the passivation layer 130, extends along the gate lines GL and the data lines DL and covers the TFT. In the exemplary embodiment shown in FIG. 2, for example, the organic pattern 142 entirely covers portions of the gate lines GL and the data lines DL proximate to the TFT.

The light-blocking pattern 144 is formed on the organic pattern 142 with substantially a same size and/or shape as the organic pattern 142. The light-blocking pattern 144 according to an exemplary embodiment of the present invention includes carbon black, for example, which is able to block light.

As shown in FIG. 3, the color filters 150 are formed in unit pixels, e.g., unit pixel areas, of the base substrate. More specifically, the color filters 150 are formed the unit pixels in an area thereof in which the light-blocking part 140 is not formed. In an exemplary embodiment of the present invention, the color filters 150 include red color filters 150, green color filters 150 and blue color filters 150.

Further, the color filters 150 disposed along the second direction DI2, for example, may display substantially a same color. More specifically, for example, the red color filters 150, the green color filters 150 and the blue color filters 150 may be alternately and sequentially disposed along the first direction DI1, while color filters 150 having substantially the same color are disposed along the second direction DI2. Accordingly, when color filters 150 having substantially the same color are disposed along the second direction DI2, the light-blocking part 140 according to an alternative exemplary embodiment need not extend along the gate lines GL, in contrast to as shown in FIG. 1. For example, the light-blocking part 140 according to an alternative exemplary embodiment may not be formed along the gate lines DL to cover the gate lines GL.

The pixel electrodes 160 according to an exemplary embodiment include a transparent conductive material, such as indium tin oxide (“ITO”) or indium zinc oxide (“IZO”), for example, and are formed on the color filters 150, as shown in FIG. 3. Each of the pixel electrodes 160 is electrically connected to the drain electrode DE through a contact hole CH formed through the passivation layer 130 and the light-blocking part 140. Each of the pixel electrodes 160 is also formed on a respective portion of the light-blocking portion 140, as shown in FIGS. 1 and 2, so that each of the pixel electrodes 160 makes electric contact with the drain electrode DE through the contact hole CH.

In an exemplary embodiment, a thickness of the light-blocking part 140 is substantially the same as a thickness of the color filter. For example, the thickness of the light-blocking part 140 and the thickness of the color filter 150 may each be in a range from approximately 3 μm to approximately 4 μm, but alternative exemplary embodiments of the present invention are not limited thereto.

In addition, a thickness of the organic pattern 142 may be substantially the same or, alternatively, greater than a thickness of the light-blocking pattern 144. I an exemplary embodiment, for example, the thickness of the organic pattern 142 may be in a range from between approximately 1.5 μm and approximately 3 μm, and the thickness of the light-blocking pattern 144 may be in a range from between approximately 1 μm and approximately 1.5 μm.

In addition, an optical density (“OD”) of the light-blocking pattern 144 according to an exemplary embodiment of the present invention is greater than approximately 4. In an exemplary embodiment in which the optical density of the light-blocking pattern 144 is 4, a ratio of light applied to the light-blocking pattern 144 (e.g., incident to the light-blocking pattern 144) to light which passes through the light-blocking pattern 144 is approximately 10,000 to 1.

Further, a dielectric constant of the light-blocking part 140 according to an exemplary embodiment is substantially equal to or less than approximately 6. In an exemplary embodiment of the present invention, for example, the dielectric constant of the light-blocking part 140 is in a range from between approximately 5.0 and approximately 5.5. In addition, the dielectric constant of the light-blocking pattern 144 according to an exemplary embodiment is greater than a dielectric constant of the organic pattern 142, so that a dielectric constant of the light-blocking part 140 decreases as the thickness of the light-blocking pattern 144 thereof decreases, e.g., becomes thinner, as best shown in FIG. 3.

A method for manufacturing display substrate according to an exemplary embodiment of the present invention will now be described in further detail.

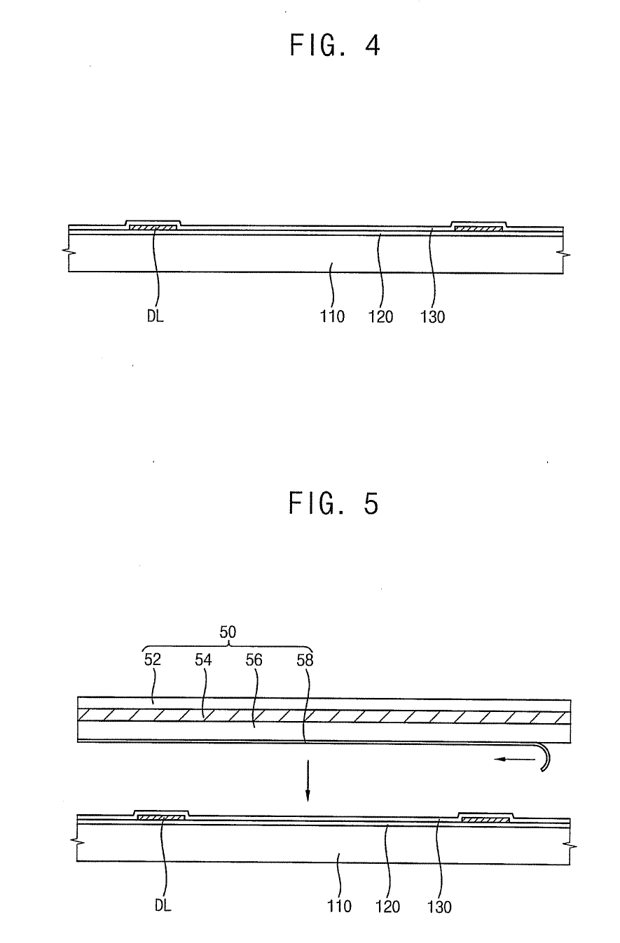

FIG. 4 is a partial cross-sectional view which illustrates a process for forming a TFT and a data line on a base substrate in a method for manufacturing a display substrate according to an exemplary embodiment of the present invention.

Referring to FIGS. 1, 2 and 4, a gate metal layer (not fully shown) is formed on the base substrate 110, and the gate line GL and the gate electrode GE are formed via patterning the gate metal layer.

The gate insulating layer 120 is then formed to cover the gate line GE and the gate electrode GE.

Then, an active layer (not fully shown) and an ohmic contact layer (not fully shown) are formed on the gate insulating layer 120, and the active pattern AP and the ohmic contact pattern OP are formed via patterning the active layer and the ohmic contact layer, respectively.

A data metal layer (not fully shown) is formed on the gate insulating layer 120 to cover the active pattern AP and the ohmic contact pattern OP. The data line DL, the source electrode SE and the drain electrode DE are then formed via patterning the data metal layer.

The ohmic contact pattern OP is patterned to include two parts, e.g., to be divided into two parts, using the source electrode SE and the drain electrode DE as a mask.

In an exemplary embodiment, after the active layer, the ohmic contact layer and the data metal layer are sequentially formed on the gate insulating layer 120, the data metal layer is first patterned, while the active layer and the ohmic contact layer are patterned thereafter.

Then, the passivation layer 130 is formed on the gate insulating layer 120 to cover the data line DL and the TFT. In this case, the passivation layer 130 includes the inorganic insulating layer including silicon oxide (“SiOx”) or silicon nitride (“SiNx”), for example. The passivation layer 130 is then patterned again to form a groove to partially expose the drain electrode DE (FIG. 2).

FIG. 5 is a partial cross-sectional view which illustrates a process for aligning a dry film in the base substrate in the method for manufacturing the display substrate according to the exemplary embodiment of the present invention shown in FIG. 4.

Referring to FIG. 5, a dry film 50 which will be attached to the base substrate 110 is disposed over the base substrate 110. Specifically, the dry film 50 is aligned facing, e.g., over and above, the base substrate 110, as shown in FIG. 5.

The dry film 50 according to an exemplary embodiment includes a base film 52, a light-blocking photosensitive film 54, an organic photosensitive film 56 and a protective film 58. More specifically, the light-blocking photosensitive film 54 is formed on the base film 52, the organic photosensitive film 56 is formed on the light-blocking photosensitive film 54, and the protective film 58 is formed on the organic photosensitive film 56, as shown in FIG. 5.

In an exemplary embodiment of the present invention, the organic photosensitive film 56 and the light-blocking photosensitive film 54 have substantially a same photoresistance type. For example, the organic photosensitive film 56 and the light-blocking photosensitive film 54 may be negative-type photo resists.

In addition, the organic photosensitive film 56 and the light-blocking photosensitive film 54 may include a solvent material, a binder material, a starter material and/or a monomer material, for example, while alternative exemplary embodiments are not limited thereto. In an exemplary embodiment, therefore, the solvent material, for example, is evaporated over time, and the binder material thereby forms a main structure of the organic photosensitive film 56. The starter material reacts with the monomer material when the light is irradiated, and the monomer material reacts with the starter material to form chains in the binder material. When the monomer material forms the chains in the binder material, the binder material is hardened.

The light-blocking photosensitive film 54 may further include carbon black, which block light more effectively than the organic photosensitive film 56.

After the dry film 50 is aligned with the base substrate 110 as shown in FIG. 5, the protective film 58 is removed (shown being removed from right to left as viewed in FIG. 5) from the organic photosensitive film 56 to expose the organic photosensitive film 56.

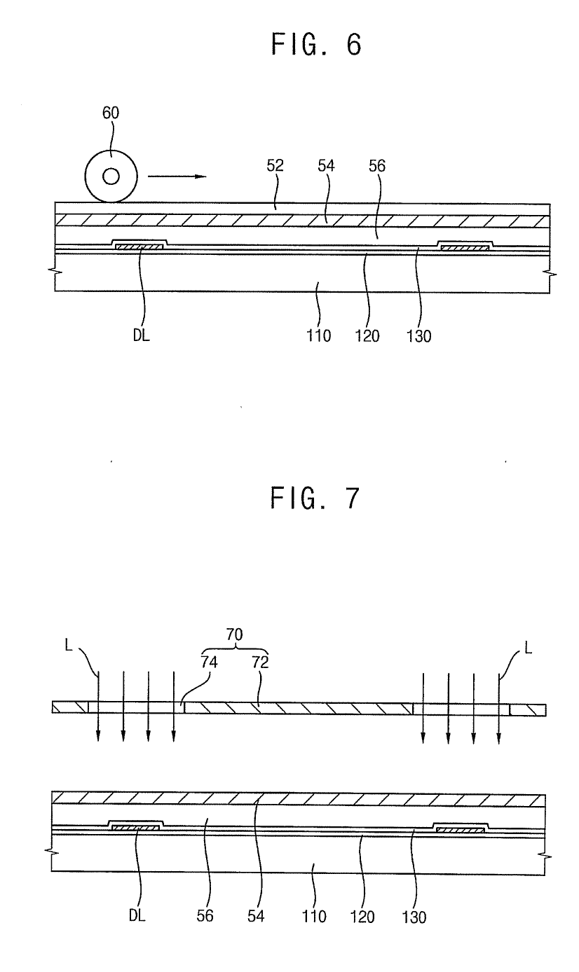

FIG. 6 is a partial cross-sectional view which illustrates a process for attaching the dry film to the base substrate in the method for manufacturing the display substrate according to the exemplary embodiment of the present invention shown in FIG. 5.

Referring to FIG. 6, after the protective film 58 is removed from the organic photosensitive film 56 (FIG. 5), the organic photosensitive film 56, having the light-blocking photosensitive film 54 and the base film 52 disposed thereon, is disposed on the base substrate 110 such that the organic photosensitive film 56 makes contact with the passivation layer 130.

Then, pressure and/or heat is applied to the base film 52 so that the organic photosensitive film 56 and the light-blocking photosensitive film 54 are attached to the passivation layer 130. In an exemplary embodiment of the present invention, for example, a pressure roller 60 applies the pressure and/or heat to the base film 52. More specifically, the pressure roller 60 moves from left to right (as viewed in FIG. 5) at a velocity in a range from approximately 0.3 m/min to approximately 0.4 m/min, so that a pressure in a range between approximately 5 kg/cm² and approximately 6 kg/cm², and/or a heat having a temperature of approximately 108° C. may be applied on the base film 52. It will be noted that alternative exemplary embodiments of the present invention are not limited to the foregoing description.

After the organic photosensitive film 56 and the light-blocking photosensitive film 54 are attached to the passivation layer 130, the base film 52 is removed from the light-blocking photosensitive layer 54, as shown in FIG. 7 and described in further detail below.

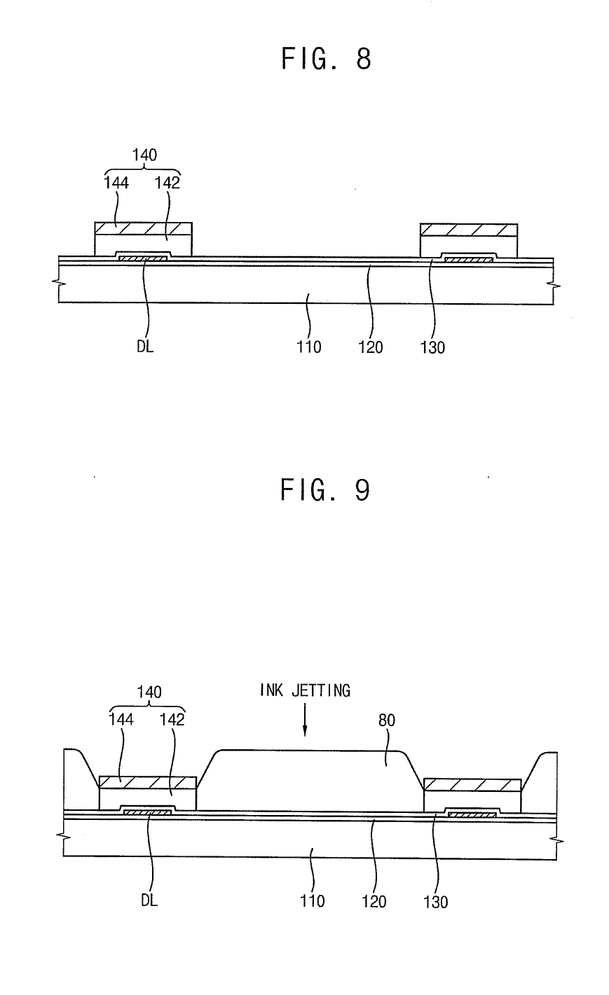

FIG. 7 is a partial cross-sectional view which illustrates a process for exposing an organic photosensitive film and a light-blocking photosensitive film attached to the base substrate in the method for manufacturing the display substrate according to the exemplary embodiment of the present invention shown in FIG. 6. FIG. 8 is a partial cross-sectional view which illustrates a process for patterning an exposed organic photosensitive film and an exposed light-blocking photosensitive film in the method for manufacturing the display substrate according to the exemplary embodiment of the present invention shown in FIG. 7.

Referring to FIGS. 7 and 8, the organic photosensitive film 56 and the light-blocking photosensitive film 54 are exposed using a mask 70. The mask 70 according to an exemplary embodiment is divided into a blocking area 72 (through which light is blocked from passing) and a transmissive area 74 (through which light is allowed to pass).

Thus, when the organic photosensitive film 56 and the light-blocking photosensitive film 54 are negative type photo resists, first portions of the organic photosensitive film 56 and the light-blocking photosensitive film 54, corresponding to the transmissive area 74 of the mask 70, are exposed and are thereby cured.

Then, second portions of the organic photosensitive film 56 and the light-blocking photosensitive film 54, e.g., portions which are not cured, are removed via an etching process, so that the organic pattern 142 and the light-blocking pattern 144 are formed. The light-blocking part 140 is formed, for example, via patterning the organic photosensitive film 56 and the light-blocking photosensitive film 54, as shown in FIG. 8.

Accordingly, the organic photosensitive film 56 is formed beneath the light-blocking photosensitive film 54, so that light-blocking photosensitive film 54 is effectively prevented from making direct contact with the passivation layer 130 of the base substrate 110. Thus, remaining portions of the light-blocking photosensitive film 54, caused by patterning the light-blocking photosensitive film 54, are effectively prevented in an exemplary embodiment of the present invention.

When the organic photosensitive film 56 and the light-blocking photosensitive film 54 are patterned, the contact hole CH is formed to at least partially expose the drain electrode DE through the passivation layer 130, as shown in FIG. 2.

FIG. 9 is a partial cross-sectional view which illustrates a process for jetting a color filter ink on a unit pixel area of the base substrate in the method for manufacturing the display substrate according to the exemplary embodiment of the present invention shown in FIG. 8.

Referring to FIG. 9, after the light-blocking part 140 is formed, a color filter ink 80 is jetted, using an ink jetting process, onto a portion of the passivation layer 130 on which the light-blocking part 140 is not formed. More specifically, in an exemplary embodiment of the present invention, the color filter ink 80 is jetted on a unit pixel area in which the light-blocking part 140 is not formed, as shown in FIG. 9.

In an exemplary embodiment, the organic pattern 142 of the light-blocking part 140 has a hydrophilic property, and thereby has a high affinity for the color filter ink 80, relative to the light-blocking pattern 144, which has a hydrophobic property and thereby has a relatively low affinity for the color filter ink 80. Thus, the color filter ink 80 jetted onto the passivation layer 130 is effectively prevented from flowing from the light-blocking part 140 into adjacent unit pixels (not shown).

In an alternative exemplary embodiment of the present invention, however, both the organic pattern 142 and the light-blocking pattern 144 may have a hydrophilic property, and thereby may both have a high affinity for the color filter ink 80. In this case, plasma (not shown) is jetted onto the light-blocking pattern 144 before the color filter ink 80 is jetted onto the passivation layer 130. Accordingly, when the plasma is jetted onto the light-blocking pattern 144, a surface of the light-blocking pattern 144 having the hydrophilic property is converted into a surface having a hydrophobic property, thereby effectively preventing the color filter ink 80 from flowing from the light-blocking part 140 into adjacent unit pixels.

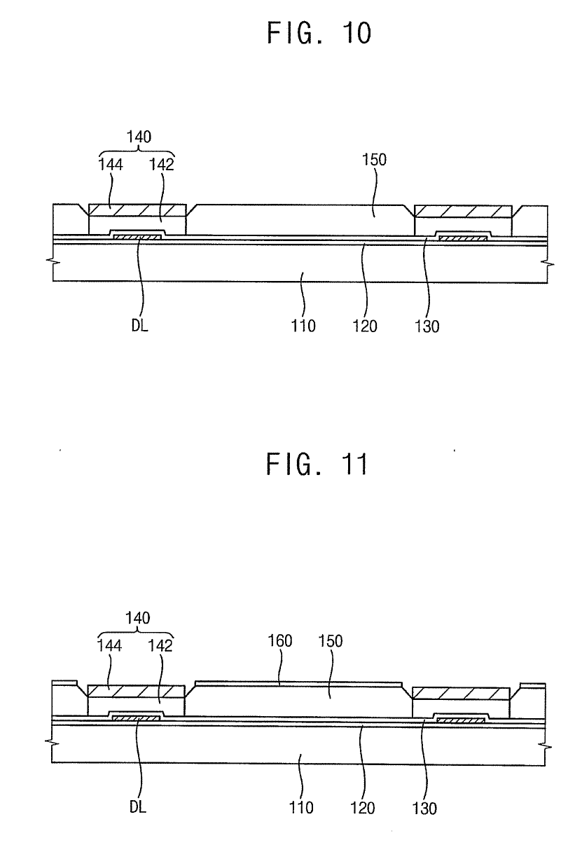

FIG. 10 is a partial cross-sectional view which illustrates a process for drying the color filter ink 80 jetted onto the passivation layer 130 of the base substrate 110 in the method for manufacturing the display substrate according to the exemplary embodiment of the present invention shown in FIG. 9.

Referring to FIG. 10, the color filter ink 80 is jetted on the passivation layer 130, and then the color filter ink 80 is dried. Specifically, when the color filter ink 80 is dried, a thickness of the color filter ink 80 is decreased, e.g., an upper surface of the color filter ink 80 (FIG. 9) moves downward toward the base substrate 110, and the color filter 150 is thereby formed, as shown in FIG. 10. In an exemplary embodiment of the present invention, the thickness of the color filter 150 is substantially the same as a thickness of the light-blocking part 140.

As the color filter ink 80 is dried and the thickness of the color filter ink 80 decreases, the upper surface of the color filter ink 80 becomes planarized, and an upper surface of the color filter 150 therefore becomes substantially flat, e.g., formed at a substantially same height above the base substrate 110 as other components thereon (such as the light-blocking part 140, for example), as shown in FIG. 10.

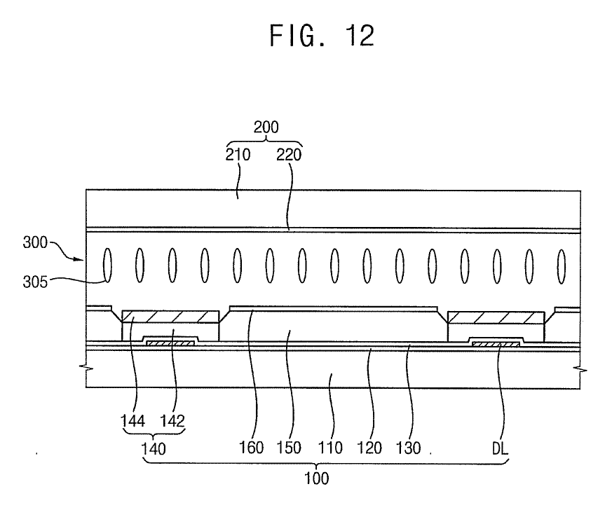

FIG. 11 is a partial cross-sectional view which illustrates a process for forming a pixel electrode on a color filter in the method for manufacturing the display substrate according to the exemplary embodiment of the present invention shown in FIG. 10.

Referring to FIG. 11, the color filter 150 is formed, as described in greater detail above with reference to FIG. 10, and then a transparent electrode layer (not fully shown) is formed on both the color filter 150 and the light-blocking part 140. Then, the transparent electrode layer is patterned to form the pixel electrode 160. In an exemplary embodiment, the pixel electrode 160 is formed on the color filter 150, and the pixel electrode 160 makes electric contact with the drain electrode DE through the contact hole CH (best shown in FIG. 2) of the light-blocking part 140.

FIG. 12 is a partial cross-sectional view of a display apparatus having the display substrate according to the exemplary embodiment of the present invention shown in FIG. 1.

Referring to FIG. 12, a display apparatus according to an exemplary embodiment of the present invention includes a first substrate 100, a second substrate 200 and a liquid crystal layer 300.

The first substrate 100 is substantially the same as the display substrate described in greater detail above with reference to FIGS. 1 to 5, and thus any repetitive detailed description thereof will hereinafter be omitted. In addition, the same reference characters refer to the same or like components between FIGS. 1 to 12.

Referring to FIG. 12, the second substrate 200 is disposed opposite to, e.g., to face, the first substrate 100. Further, the second substrate 200 according to an exemplary embodiment includes a counter substrate 210 facing the first substrate 100, and a common electrode 220 formed on a surface of the counter substrate 210 facing the first substrate 100. The common electrode 220 includes a transparent conductive material, for example.

The liquid crystal layer 300 is disposed between the first substrate 100 and the second substrate 200. Liquid crystal molecules 305 are disposed in the liquid crystal layer 300. In an exemplary embodiment of the present invention, an orientation of the liquid crystal molecules 305 is determined by an electric field generated between the pixel electrode 160 and the common electrode 220, and a light transmissivity of the liquid crystal layer 300 is thereby changed based an intensity of the electric field.

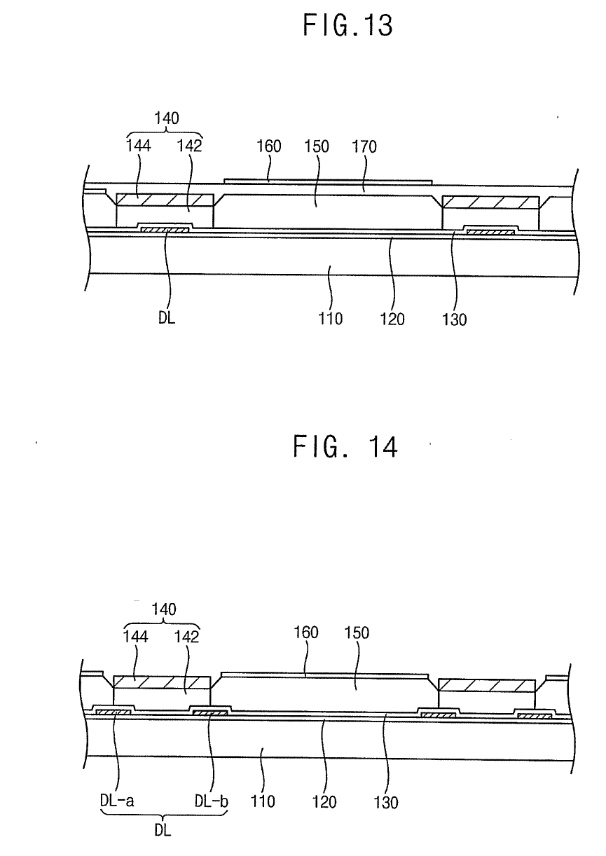

FIG. 13 is a partial cross-sectional view of a display substrate according to an alternative exemplary embodiment of the present invention.

The exemplary embodiment of the present invention shown in FIG. 13 is substantially the same as the display substrate according to the exemplary embodiment shown in FIG. 3 except for an organic protective layer. Thus, the same reference numerals will be used to refer to the same or like parts as those described in the exemplary described in greater detail above with reference to FIG. 3, and any repetitive detailed explanation thereof will hereinafter be omitted.

Referring to FIG. 13, a display substrate according to an alternative exemplary embodiment of the present invention further includes an organic protective layer 170 formed on the base substrate 110. The organic protective layer 170 covers the light-blocking part 140 and the color filters 150. In addition, the organic protective layer 170 planarizes a surface of the display substrate, as shown in FIG. 13.

The pixel electrodes 160 are formed on the organic protective layer 170. In addition, the pixel electrodes 160 correspond to associated color filters 150. Further, the to pixel electrodes 160 make electric contact with the drain electrode DE through a contact hole CH (FIGS. 1 and 2) formed through the light-blocking part 140 and the organic protective layer 150 (FIG. 2).

A method for manufacturing the display substrate according to the exemplary embodiment of the present invention shown in FIG. 13 will now be described in further detail.

The processes for forming the color filter 150 in the method for manufacturing the display substrate according to the exemplary embodiment of the present invention are substantially the same as those described in greater detail above with reference to FIGS. 4 to 10. Thus, any repetitive detailed description thereof will hereinafter be omitted.

Still referring to FIG. 13, the organic protective layer 170 is formed on the base substrate 110 to cover the light-blocking part 140 and the color filters 150 after the color filter 150 is formed. In an exemplary embodiment of the present invention, a surface of the organic protective layer 170 is planarized.

Then, the organic protective layer 150 is patterned so that the drain electrode DE is exposed through the contact hole CH formed through the passivation layer 130 and the light-blocking part 140 (best shown in FIG. 2).

Then, a transparent electrode layer (not fully shown) is formed on the organic protective layer 170 and the transparent electrode layer is patterned to form the pixel electrode 160. In this case, the pixel electrode 160 is formed on the color filter 150, and makes electric contact with the drain electrode DE through the contact hole CH formed through the passivation layer 130, the light-blocking part 140 and the organic protective layer 150.

A display apparatus according to an alternative exemplary embodiment of the present invention includes the display substrate according to the exemplary embodiment of the present invention shown in FIG. 13.

FIG. 14 is a partial cross-sectional view of a display substrate according to yet another alternative exemplary embodiment of the present invention.

Referring to FIG. 14, the display substrate according to the exemplary embodiment of the present invention shown in FIG. 14 is substantially the same as the display substrate according to exemplary embodiments shown in FIGS. 1 to 3 except for a data line DL. Thus, the same reference numerals will be used to refer to the same or like parts as those described in FIGS. 1 to 3, and any repetitive detailed description thereof will hereinafter be omitted.

The data line DL according to an alternative exemplary embodiment of the present invention includes a first data lines DL-a and a second data line DL-b disposed in parallel with each other and both arranged in substantially the second direction DI2 (FIG. 1).

In an exemplary embodiment, the first data line DL-a provides a first data voltage having a first level to a pixel electrode 160. The second data line DL-b is adjacent to the first data line DL-a, and provides a second data voltage having a second level, lower than the first level, to the pixel electrode 160.

Each of the pixel electrodes 160 includes a high-voltage electrode and a low-voltage electrode, spaced apart from the high voltage electrode; to enhance a viewing angle of an image displayed using the pixel electrodes 160. More specifically, for example, the first data line DL-a according to an exemplary embodiment may provide the first data voltage to the high-voltage electrode of a pixel electrode 160 disposed at a left side of the first data line DL-a, while the second data line DL-b may provide the second data voltage to the low-voltage electrode of the pixel electrode 160 disposed at a right side of the second data line DL-b.

The light-blocking part 140 is disposed between the first data line DL-a and the second data line DL-b, and at least partially overlaps both the first data line DL-a and the second data line DL-b, as shown in FIG. 14. In an exemplary embodiment of the present invention, for example, the light-blocking part 140 overlaps both of the first data line DL-a and the second data line DL-b from a central portion of the first data line DL-a along the first direction DI1 to a central portion of the second data line DL-b along the first direction DI1.

A method for manufacturing the display substrate according to the exemplary embodiment of the present invention shown in FIG. 14 will hereinafter be described in further detail.

The method for manufacturing the display substrate according to the exemplary embodiment shown in FIG. 14 is substantially same as the method for manufacturing the display substrate described in greater detail above with reference to FIGS. 4 to 11, except patterning a data metal layer, and thus any repetitive detailed description thereof will hereinafter be omitted.

After the active pattern AP and the ohmic contact pattern OP are formed, the data metal layer (not fully shown) is formed on the gate insulating layer 120 to cover the active pattern AP and the ohmic contact pattern OP.

Then, the data metal layer is patterned to form the data line DL, the source electrode SE and the drain electrode DE. In the exemplary embodiment of the present invention shown in FIG. 14, the data line DL includes the first data line DL-a and the second data line DL-b disposed substantially in parallel with the first data line DL-a.

A display apparatus according to an alternative exemplary embodiment of the present invention includes the display substrate shown in FIG. 14.

The display apparatus having the display substrate according to the exemplary embodiment shown in FIG. 14 is substantially the same as the display apparatus described above in greater detail with reference to FIG. 12, except for the first substrate (which is substantially the same as the display substrate according to the exemplary embodiment of the present invention shown in FIG. 14), and thus any repetitive detailed description thereof has been omitted.

Thus, according to exemplary embodiments of the present invention, an organic photosensitive film is formed beneath a light-blocking photosensitive film, and the light-blocking photosensitive film does not make direct contact with a passivation layer thereunder. Thus, a remaining portion of the light-blocking photosensitive layer caused by patterning the light-blocking photosensitive film is effectively prevented from remaining on the passivation layer, and a display quality of an image displayed on a display apparatus having the display substrate according to an exemplary embodiment of the present invention is substantially enhanced.

In addition, a thickness of the light-blocking part is substantially the same as a thickness of the color filter, to thereby planarize a surface of the display substrate. Thus, when the organic photosensitive film is formed beneath the light-blocking photosensitive film, a thickness of the light-blocking photosensitive film may be relatively thin, and the light-blocking pattern may be precisely formed at an accurate position and having a predetermined shape when patterning the light-blocking photosensitive film.

Further, the organic pattern is formed beneath the light-blocking pattern so that the thickness (and corresponding dielectric constant thereof) of the light-blocking pattern is decreased, since when dielectric constant of the light-blocking part is relatively large, the light-blocking part has an adverse affect on a signal provided via the gate line or the data line. Thus, in decreasing the dielectric constant of the light-blocking part effectively prevents the light-blocking part from having the adverse affect on the signal.

According to exemplary embodiments of the present invention as described herein, a display substrate has advantages which include, but are not limited to, an improved display quality and increased efficiency of a manufacturing method of the display substrate.

The exemplary embodiments described herein are illustrative of the present invention, and are not to be construed as limiting thereof. Although exemplary embodiments of the present invention have been described, those having ordinary skill in the art will readily appreciate that modifications thereof are possible without departing from the spirit or scope of the present invention.

The present invention should not be construed as being limited to the exemplary embodiments set forth herein. Rather, these exemplary embodiments are provided so that this disclosure will be thorough and complete and will fully convey the concept of the present invention to those skilled in the art.

While the present invention has been particularly shown and described with reference to exemplary embodiments thereof, it will be understood by those of ordinary skill in the art that various changes in form and details may be made therein without departing from the spirit or scope of the present invention as defined by the following claims.

What is claimed is:

1. A display substrate comprising:
a base substrate;
a signal line formed on the base substrate;
a thin-film transistor formed on the base substrate and electrically connected to the signal line;
a pixel electrode formed in a unit pixel area of the base substrate and electrically connected to the thin-film transistor;
a color filter formed in the unit pixel area; and
a light-blocking part comprising:
an organic pattern formed on the base substrate; and
a light-blocking pattern formed on the organic pattern, wherein
the organic pattern is formed along a longitudinal axis of the signal line to define at least a portion of a periphery of the color filter,
the organic pattern covers the thin-film transistor, and
a size and a shape of the light-blocking pattern are substantially the same as a size and a shape of the organic pattern.

2. The display substrate of claim 1, wherein the organic pattern has a hydrophilic property, and the light-blocking pattern has a hydrophobic property.

3. The display substrate of claim 1, wherein a thickness of the light-blocking part is approximately the same as a corresponding thickness of the color filter.

4. The display substrate of claim 1, wherein a thickness of the organic pattern is approximately equal to or greater than a corresponding thickness of the light-blocking pattern.

5. The display substrate of claim 1, further comprising an organic protective layer formed between the pixel electrode and the color filter to cover the color filter and the light-blocking part.

6. The display substrate of claim 1, wherein
the pixel electrode is formed on the color filter, and
the pixel electrode makes electrical contact with a drain electrode of the thin-film transistor through a contact hole formed through the light-blocking part.

7. The display substrate of claim 1, further comprising a plurality of the signal lines, wherein signal lines of the plurality of the signal lines comprise:
a gate line formed along a first direction and electrically connected to a gate electrode of the thin-film transistor; and
a data line formed along a second direction, substantially perpendicular to the first direction, and electrically connected to a source electrode of the thin-film transistor.

8. The display substrate of claim 7, wherein the data line comprises:
a first data line which provides a first data voltage having a first level to the pixel electrode; and
a second data line disposed adjacent to the first data line and which provides a second data voltage having a second level to the pixel electrode, wherein the second level is less than the first level.

9. The display substrate of claim 8, wherein
the light-blocking part is disposed between the first data line and the second data line, and
the light-blocking part at overlaps at least a portion of the first data line and the second data line.

10. A method for manufacturing a display substrate, the method comprising:
forming a signal line and a thin-film transistor electrically connected to the signal line on a base substrate;
forming a light-blocking part on the base substrate, the light-blocking part including an organic pattern and a light-blocking pattern;
forming a color filter in a unit pixel area of the base substrate in which the light-blocking part is not formed; and
forming a pixel electrode, electrically connected to the thin-film transistor, on the color filter, wherein
the organic pattern is formed along a longitudinal axis of the signal line and defines at least a portion of a periphery of the color filter,
the organic pattern covers the thin-film transistor,
the light-blocking pattern is formed on the organic pattern, and
a size and a shape of the light-blocking pattern are substantially the same as a size and a shape of the organic pattern.

11. The method of claim 10, wherein the forming the light-blocking part comprises:
sequentially forming an organic photosensitive film and a light-blocking photosensitive film on the base substrate to cover the signal line and the thin-film transistor; and
forming the organic pattern and the light-blocking pattern by patterning the organic photosensitive film and the light-blocking photosensitive film using a photolithography process.

12. The method of claim 11, wherein the sequentially forming the organic photosensitive film and the light-blocking photosensitive film comprise:
attaching a dry film to the base substrate, the dry film including a base film having the light-blocking photosensitive film and the organic photosensitive film sequentially formed thereon; and
removing the base film from the light-blocking photosensitive film and the organic photosensitive film.

13. The method of claim 12, wherein the attaching the dry film to the base substrate comprises:
aligning the dry film on the base substrate; and
attaching the organic photosensitive film and the light-blocking photosensitive film on the base substrate by at least one of pressing and heating the dry film.

14. The method of claim 11, wherein the organic photosensitive film and the light-blocking photosensitive film comprise a same type of photo resist.

15. The method of claim 14, wherein the organic photosensitive film and the light-blocking photosensitive film comprise a negative type photo resist.

16. The method of claim 10, wherein the forming the color filter comprises:
jetting a color filter ink on the unit pixel area of the base substrate; and
drying the color filter ink to form the color filter.

17. The method of claim 16, wherein
the organic pattern has a hydrophilic property to have a first affinity for the color filter ink,
the light-blocking pattern has a hydrophobic property to have a second affinity for the color filter ink, and
the first affinity for the color filter ink is greater than the second affinity for the second color filter ink.

18. The method of claim 16, wherein a thickness of the color filter is approximately the same as a corresponding thickness of the light-blocking part.

19. A display apparatus comprising:
a first substrate;
a second substrate facing the first substrate; and
a liquid crystal layer disposed between the first substrate and the second substrate, wherein the first substrate comprises:
a base substrate;
a signal line formed on the base substrate;
a thin-film transistor formed on the base substrate and electrically connected to the signal line;
a pixel electrode formed in a unit pixel area of the base substrate and electrically connected to the thin-film transistor;
a color filter formed in the unit pixel area; and
a light-blocking part including an organic pattern formed on the base substrate and a light-blocking pattern formed on the organic pattern, wherein
the organic pattern is formed along a longitudinal axis of the signal line to define at least a portion of a periphery of the color filter,
the organic pattern covers the thin-film transistor, and
a size and a shape of the light-blocking pattern are substantially the same as a size and a shape of the organic pattern.

20. The display apparatus of claim 19, wherein the second substrate comprises:
a counter substrate disposed on the second substrate; and
a common electrode formed on a surface of the counter substrate which faces the first substrate.
